(19) United States
(12) Patent Application Publication
(10) Pub. No.: US 2025/0280607 A1
(43) Pub. Date: Sep. 4, 2025

(54) SEMICONDUCTOR DEVICE INCLUDING DTI REGION AND METHOD OF MANUFACTURING SAME

(71) Applicant: DB HiTek Co., Ltd., Bucheon-si (KR)

(72) Inventor: Han Seok KO, Eumseong-gun (KR)

(21) Appl. No.: 18/635,646

(22) Filed: Apr. 15, 2024

(30) Foreign Application Priority Data
Mar. 4, 2024 (KR) 10-2024-0030667

(51) Int. Cl. H01L 27/02; H01L 21/02; H01L 21/762; H01L 21/764

(52) U.S. Cl. CPC H10D 89/10; H01L 21/02362; H01L 21/76232; H01L 21/764

(57) ABSTRACT

Proposed are a semiconductor device including a DTI region and a method of manufacturing the same, which enable easy formation of a DTI region including an upper region and a lower region by having an outer surface of the upper region in the DTI region be inclined as the outer surface of the upper region extends downward. A semiconductor device including a DTI region may comprise: a substrate; and a DTI region disposed within the substrate, wherein the DTI region comprises: an upper region extending downward from a surface of the substrate to a first predetermined depth; and a lower region extending downward from a bottom of the upper region to a second predetermined depth within the substrate, wherein the upper region comprises an inclined surface that becomes steeper as an outer surface of the upper region extends downward.

### CROSS REFERENCE TO RELATED APPLICATION

The present application claims priority to Korean Patent Application No. 10-2024-0030667, filed Mar. 4, 2024, the entire contents of which is incorporated herein for all purposes by this reference.

### BACKGROUND OF THE INVENTION

### Field of the Invention

The present disclosure relates to a semiconductor device including a DTI region and a method of manufacturing the same and, more particularly, to a semiconductor device including a DTI region and a method of manufacturing the same, which enable easy formation of a DTI region including the upper region and a lower region by having an outer surface of the upper region in the DTI region be inclined as the upper region extends downward.

### Description of the Related Art

In recent Bipolar-CMOS-DMOS (BCD) processes, it is required to achieve a high breakdown voltage of 100V or more, and according to this high voltage requirement, a process of forming a deep trench isolation (DTI) region is used to prevent an increase in leakage current through electrical isolation between adjacent devices.

FIG. 1 is a cross-sectional view showing a semiconductor device including a conventional DTI region.

Hereinafter, the structure of a conventional DTI region and resulting problems will be described in detail.

Referring to FIG. 1, in a conventional semiconductor device 9, a DTI region 910 may be formed in a substrate 901. The DTI region 910 is an area gap-filled by an insulating film, and may include: an upper region 911; and a lower region 913 extending downward from the lower end of the upper region 911 within the substrate 901. In addition, a pre-metal dielectric (PMD) layer 920 may be formed on the substrate 901. In the conventional DTI region 910, the upper region 911 extends downwardly within the PMD layer 920 and the substrate 901 (or STI region 930) such that the outer surface thereof is substantially perpendicular to the surface of the substrate 901, while the lower region 913 may be formed to have a tapered width at the lower end of the upper region 911 and extend downward to a predetermined depth.

In order to form the conventional DTI region 910 as above, after forming a first trench (not shown) in which the upper region 911 will be formed in the PMD layer 920 and the substrate 901, a second trench (not shown) should be formed below the first trench in the substrate 901. Then, a process of gap filling the insulating film in the first trench and the second trench is performed. At this time, since the outer surface of the first trench corresponding to the shape of the upper region 911 extends downward so as to be substantially perpendicular to the surface of the substrate 901, overhang is generated by the gap-filled insulating film. Correspondingly, an etch-back process is performed on the insulating film to lower (reduce) the height (or depth) of the upper part of an air gap AG formed at a relatively high position within the DTI region 910 due to the overhang. Then, the insulating film gap fill process in the first and second trenches is performed again. That is, when forming the conventional DTI region 910, the overall process may become complicated because the first insulating film gap fill process, the etch-back process, and the second insulating film gap fill process need to be performed after forming the PMD layer 920 on the substrate 901.

Moreover, because the upper end of the air gap AG is formed at a relatively high position within the DTI region 910, the possibility of cracks occurring in the air gap AG cannot be ruled out in a subsequent process. That is, since stress is concentrated in the air gap AG in the DTI region 910, cracks may occur along the upper side of the air gap AG. When a subsequent process such as a contact process is performed, for example, in a state where a crack occurring in the DTI region, tungsten (W) may remain inside the space created by the crack, causing a defect in the device.

To solve the above problems, the inventor of the present disclosure proposes a novel semiconductor device with improved structure, the details of which will be described later.

### DOCUMENTS OF RELATED ART

(Patent Document 0001) Korean Patent Application Publication No. 10-2003-0000592 “METHOD FOR MANUFACTURING OF SEMICONDUCTOR DEVICE WITH STI/DTI STRUCTURE”

### SUMMARY OF THE INVENTION

The present disclosure has been made to solve the problems of the related art, and an objective of the present disclosure is to provide a semiconductor device including a DTI region and a method of manufacturing the same, which prevent the upper part of an air gap from being formed at a relatively high height/depth due to overhang on the border of an substrate and a first trench when gap filling an insulating film by making an upper region of a DTI region slanted.

An objective of the present disclosure is to provide a semiconductor device including a DTI region and a method of manufacturing the same, which prevent defects from occurring in the device during a subsequent process by reducing the possibility of a crack extending to the upper part of an insulating film even if the crack occurs in the insulating film at the upper part of an air gap by lowering (reducing) the height/depth of the upper part of the air gap.

An objective of the present disclosure is to provide a semiconductor device including a DTI region and a method of manufacturing the same, which improve process efficiency by omitting additional etch-back and secondary gap fill processes by completing a DTI region with one gap fill process in first and second trenches.

An objective of the present disclosure is to provide a semiconductor device including a DTI region and a method of manufacturing the same, which allow the upper surface of a PMD layer to be flattened by forming a compensation film on an insulating film on a substrate.

An objective of the present disclosure is to provide a semiconductor device including a DTI region and a method of manufacturing the same, which enable easy control of the overall thickness of a PMD layer by forming a capping layer on a compensation film in some cases.

The present disclosure may be implemented by an embodiment having the following configuration to achieve the above-described objectives.

According to an embodiment of the present disclosure, there is provided a semiconductor device including a DTI region. The semiconductor device includes: a substrate; and a DTI region disposed within the substrate, wherein the DTI region may include: an upper region extending downward from a surface of the substrate to a first predetermined depth; and a lower region extending downward from a bottom of the upper region to a second predetermined depth within the substrate, wherein the upper region may include an inclined surface that becomes steeper as an outer surface thereof extends downward.

According to another embodiment of the present disclosure, in the semiconductor device including a DTI region, an upper part of the upper region may have a lateral width wider than a lateral width of a lower part of the upper region.

According to still another embodiment of the present disclosure, in the semiconductor device including a DTI region, the inclined surface may have an inclination angle within a range of of 30° to 80°.

According to still another embodiment of the present disclosure, in the semiconductor device including a DTI region, the DTI region may be formed by a one-time insulating film gap fill process.

According to still another embodiment of the present disclosure, the semiconductor device including a DTI region may further include: an air gap defined in the DTI region.

According to still another embodiment of the present disclosure, the semiconductor device including a DTI region may further include: an insulating film disposed on the surface of the substrate, wherein the inclined surface of the upper region may have a first inclination angle, wherein the insulating film may include a second inclined surface that sinks downward at a second inclination angle above the air gap, and wherein the second inclination angle may have a different value from the first inclination angle. According to still another embodiment of the present disclosure, in the semiconductor device including a DTI region, the insulating film may be formed substantially simultaneously with the DTI region.

According to still another embodiment of the present disclosure, the semiconductor device including a DTI region may further include: a compensation film disposed on the insulating film, wherein the compensation film may have a substantially flat upper surface.

According to still another embodiment of the present disclosure, the semiconductor device including a DTI region may further include: a capping layer configured to control an overall thickness of a PMD layer, the capping layer being disposed on the compensation film.

According to still another embodiment of the present disclosure, there is provided a semiconductor device including a DTI region. The semiconductor device includes: a substrate; a gate electrode disposed on the substrate; a drain region disposed on a substrate surface side within the substrate; a source region spaced apart from the drain region and disposed on the substrate surface side within the substrate; a body region surrounding the source region; and a DTI region disposed within the substrate, wherein the DTI region may include: an upper region whose outer surface extends downward from a surface of the substrate to a first predetermined depth; and a lower region extending downward from a bottom of the upper region to a second predetermined depth within the substrate.

According to still another embodiment of the present disclosure, the semiconductor device including a DTI region may further include: an STI region disposed on a side that overlaps the DTI region within the substrate.

According to still another embodiment of the present disclosure, in the semiconductor device including a DTI region, the upper region may have a wider lateral width than a lateral width of the lower region.

According to still another embodiment of the present disclosure, in the semiconductor device including a DTI region, an upper part of the upper region may have a lateral width wider than a lateral width of a lower part of the upper region.

According to still another embodiment of the present disclosure, the semiconductor device including a DTI region may further include: a first buried layer disposed in the substrate; a second buried layer disposed within the substrate and below the first buried layer; a high voltage well region connected to a side of the second buried layer; and a deep well region surrounding the drain region within the substrate and disposed on the high voltage well region.

According to still another embodiment of the present disclosure, in the semiconductor device including a DTI region, the upper region may be formed using a mask pattern, wherein the mask pattern is formed such that a side of the substrate where the upper region is to be formed may be open, and outer surfaces of the mask pattern facing each other may be inclined downward and a separation distance between the outer surfaces becomes narrower as the outer surfaces extend downward.

According to an embodiment of the present disclosure, there is provided a method of manufacturing a semiconductor device including a DTI region. The method includes: forming, at a predetermined location in a substrate, a first trench whose inner walls extend and incline downward; forming a second trench by etching the substrate under the first trench; and completing an insulating film and a DTI region by depositing a first insulating film on the substrate and gap-filling the first insulating film in the first trench and the second trench.

According to another embodiment of the present disclosure, the method of manufacturing a semiconductor device including a DTI region may further include: completing a compensation film on the insulating film on the substrate.

According to still another embodiment of the present disclosure, in the method of manufacturing a semiconductor device including a DTI region, the completing a compensation film may include: depositing a second insulating film on the insulating film; and flattening an upper surface of the second insulating film. According to still another embodiment of the present disclosure, the method of manufacturing a semiconductor device including a DTI region may further include: depositing a capping layer on the compensation film.

According to still another embodiment of the present disclosure, in the method of manufacturing a semiconductor device including a DTI region, the first trench may be formed so that the inner walls thereof facing each other may be adjacent to each other as the inner walls extend downward.

The present disclosure has the following effects by the above configurations.

According to the present disclosure, by making an upper region of a DTI region slanted, it is possible to prevent the upper part of an air gap from being formed at a relatively high height/depth due to overhang on the border of an substrate and a first trench when gap filling an insulating film.

In addition, according to the present disclosure, by lowering (reducing) the height/depth of the upper part of an air gap to reduce the possibility of a crack extending to the upper part of an insulating film even if the crack occurs in the insulating film at the upper part of the air gap, it is possible to prevent defects from occurring in the device during a subsequent process.

In addition, according to the present disclosure, by completing a DTI region with one gap fill process in first and second trenches, it is possible to improve process efficiency by omitting additional etch-back and secondary gap fill processes.

In addition, according to the present disclosure, by forming a compensation film on an insulating film on a substrate, the upper surface of a PMD layer can be flattened.

Furthermore, according to the present disclosure, by forming a capping layer on a compensation film in some cases, the overall thickness of a PMD layer can be easily controlled.

Meanwhile, it should be added that even if effects are not explicitly mentioned herein, the effects described in the following specification expected by the technical features of the present disclosure and their potential effects are treated as if they were described in the specification of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view showing a semiconductor device including a conventional DTI region;

FIG. 2 is a cross-sectional view showing a semiconductor device including a DTI region according to an embodiment of the present disclosure;

FIG. 3 is an enlarged view of a DTI region according to FIG. 2; and

FIGS. 4 to 12 are cross-sectional views showing a method of manufacturing a semiconductor device including a DTI region according to an embodiment of the present disclosure.

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those of ordinary skill in the art.

As used herein, the singular form may include the plural form unless the context clearly indicates otherwise. In addition, as used herein, “comprise” and/or “comprising” specify the presence of the recited shapes, numbers, steps, operations, members, elements, and/or groups thereof, but do not exclude the presence or addition of one or more other shapes, numbers, steps, operations, members, elements, and/or groups thereof.

Hereinafter, it should be noted that when one component (or layer) is described as being disposed on another component (or layer), one component may be disposed directly on another component, or another component(s) or layer(s) may be located between the components. In addition, when one component is expressed as being directly disposed on or above another component, no other component(s) are located between the components. Moreover, being located on “top”, “upper”, “lower”, “top”, “bottom” or “one (first) side” or “side” of a component means a relative positional relationship.

In addition, it should be noted that, where certain embodiments are otherwise feasible, certain process sequences may be performed other than those described below. For example, two processes described in succession may be performed substantially simultaneously or in the reverse order.

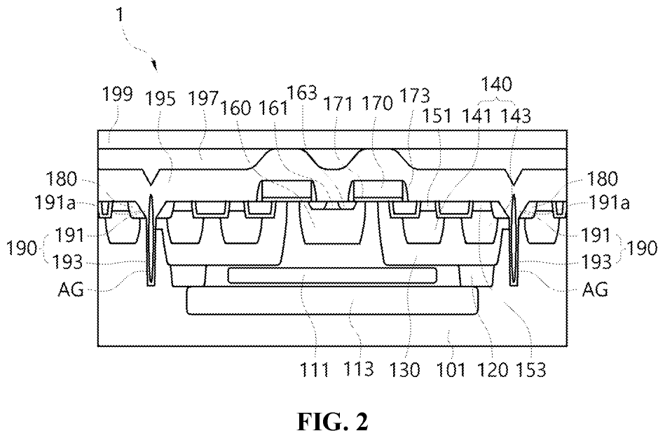

FIG. 2 is a cross-sectional view showing a semiconductor device including a DTI region according to an embodiment of the present disclosure.

Hereinafter, a semiconductor device 1 including a DTI region according to an embodiment of the present disclosure will be described in detail with reference to the accompanying drawings.

Referring to FIG. 2, the present disclosure relates to a semiconductor device 1 including a DTI region and, more particularly, to a semiconductor device 1 including a DTI region that enables easy formation of a DTI region by having the outer surface of an upper region in the DTI region including the upper region and a lower region be inclined as the outer surface of the upper region extends downward.

In the semiconductor device 1 including a DTI region according to an embodiment of the present disclosure, a substrate 101 may be formed. A well region used as an active region will be formed in the substrate 101, and the active region may be defined by an STI region 180 as a device isolation layer. In addition, the substrate 101 may be a substrate doped with a first conductivity type, a P-type diffusion region disposed in the substrate, or may include a P-type epitaxial layer epitaxially grown on the substrate. The STI region 180 may be formed by using a shallow trench isolation (STI) process, but there is no particular limitation thereon. In the drawing, the STI region 180 overlaps a DTI region 190, but this is only an example. It should be noted that the STI region 180 and a DTI region 190 may be formed in physically distinguishable locations within the substrate 101.

A first buried layer 111 and a second buried layer 113 may be formed in the substrate 101. As an example, the first buried layer 111 may be formed on one side above the second buried layer 113. In addition, a high voltage well region 120 may be formed to be connected to one side of the second buried layer 113. The high voltage well region 120 is an impurity doped region (HVNWELL) of a second conductivity type and may be formed within the substrate 101 and on the second buried layer 113. The first buried layer 111 described above may be an impurity doped region of the first conductivity type, and the second buried layer 113 may be an impurity doped region of the second conductivity type. It should be noted that the first buried layer 111 and the high voltage well region 120 are not essential components of the present disclosure and may be omitted in some cases.

A deep well region 130 may be formed within the substrate 101 and on the high voltage well region 120. One side of the deep well region 130 is connected to the high voltage well region 120, and the deep well region 130 may be a second conductivity type impurity doped region (DNWELL). In some cases, the deep well region 130 may be formed to be directly connected to the second buried layer 113.

In the deep well region 130, a well region 140 (in a pair 141 and 143) of the second conductivity type, for example, may be formed, and a drain region 151 may be formed in the first well region 141 and a highly doped region 153 may be formed in the second well region 143. The drain region 151 is a doped region of the second conductivity type and is doped with impurities at a higher concentration than the first well region 141. The highly doped region 153 is also a doped region of the second conductivity type and may be doped with impurities at a higher concentration than the second well region 143. The drain region 151 and the highly doped region 153 may be spaced apart from each other by the STI region.

In addition, the drain region 151 and the highly doped region 153 are preferably formed on the surface of the substrate 101. The above-mentioned highly doped region 153 may perform the function of a guard ring together with the second well region 143 and the high voltage well region 120 to reduce leakage current and improve a safe operating area (SOA). The drain region 151 may be electrically connected to a drain electrode (not shown), and the first well region 141 surrounding the drain region 151 is a drain extension region and may improve breakdown voltage characteristics of a high-voltage semiconductor device.

A body region 160 is formed within the substrate 101. The body region 160 is a highly doped impurity region of the first conductivity type and may be spaced apart from the deep well region 130 or may be formed to contact each other. A source region 163 is formed in the body region 160 and on the surface side of the substrate 101. The source region 163 is a region doped with a high concentration of impurities of the first conductivity type and may be electrically connected to a source electrode (not shown). In addition, a body contact region 161 may be formed within the body region 160 and on a side adjacent to or in contact with the source region 163. The body contact region 161 may be a doped region with a high concentration of impurities of the first conductivity type.

A gate electrode 170 is formed on the substrate 101. To be specific, within the active region, the gate electrode 170 may be formed between the drain region 151 and the source region 163. The gate electrode 170 is formed on a channel region, and the channel region may be turned on or off by a gate voltage applied to the gate electrode 170. The gate electrode 170 may be made of, for example, any one of conductive polysilicon, metal, conductive metal nitride, and combinations thereof, and may be formed by a CVD, PVD, ALD, MOALD, or MOCVD process, etc.

A gate insulating film 171 is formed between the gate electrode 170 and the surface of the substrate 101. The gate insulating film 171 may be made of any one of a silicon oxide film, a high-k dielectric film, and a combination thereof. In addition, the gate insulating film 171 may be formed by an ALD, CVP, or PVD process.

The sidewall of the gate electrode 170 may be covered with a gate spacer 173, and the gate spacer 173 may be made of any one of an oxide film, a nitride film, and a combination thereof.

In addition, the DTI region 190 may be formed within the substrate 101 to a predetermined depth of the substrate 101. As previously described, the DTI region 190 may be formed at a location that overlaps the STI region 180, or may be formed at a location that is physically separable from the STI region 180. The DTI region 190 is an area gap-filled by an insulating film, and may include: an upper region 191; and a lower region 193 extending downward from the lower end of the upper region 191 within the substrate 101. As an example, when the DTI region 190 overlaps the STI region 180, the lower end of the upper region 191 may be formed at substantially the same depth within the substrate 101 as the lower end of the STI region 180, but the scope of the present disclosure is not limited thereto.

Below, before describing the DTI region 190 according to an embodiment of the present disclosure in detail, the structure of a conventional DTI region and the problems resulting therefrom will be described in detail.

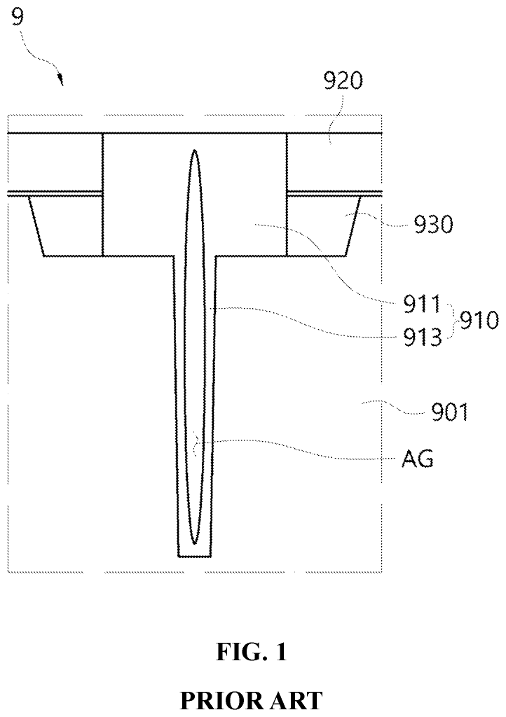

Referring to FIG. 1, in a conventional semiconductor device 9, a DTI region 910 may be formed in a substrate 901. The DTI region 910 is an area gap-filled by an insulating film, and may include: an upper region 911; and a lower region 913 extending downward from the lower end of the upper region 911 within the substrate 901. In addition, a pre-metal dielectric (PMD) layer 920 may be formed on the substrate 901. In the conventional DTI region 910, the upper region 911 extends downwardly within the PMD layer 920 and the substrate 901 (or STI region 930) such that the outer surface thereof is substantially perpendicular to the surface of the substrate 901, while the lower region 913 may be formed to have a tapered width at the lower end of the upper region 911 and extend downward to a predetermined depth.

In order to form the conventional DTI region 910 as above, after forming a first trench (not shown) in which the upper region 911 will be formed in the PMD layer 920 and the substrate 901, a second trench (not shown) should be formed below the first trench in the substrate 901. Then, a process of gap filling the insulating film in the first trench and the second trench is performed. At this time, since the outer surface of the first trench corresponding to the shape of the upper region 911 extends downward so as to be substantially perpendicular to the surface of the substrate 901, overhang is generated by the gap-filled insulating film. Correspondingly, an etch-back process is performed on the insulating film to lower (reduce) the height (or depth) of the upper part of an air gap AG formed at a relatively high position within the DTI region 910 due to the overhang. Then, the insulating film gap fill process in the first and second trenches is performed again. That is, when forming the conventional DTI region 910, the overall process may become complicated because the first insulating film gap fill process, the etch-back process, and the second insulating film gap fill process need to be performed after forming the PMD layer 920 on the substrate 901.

Moreover, because the upper end of the air gap AG is formed at a relatively high position within the DTI region 910, the possibility of cracks occurring in the air gap AG cannot be ruled out in a subsequent process. That is, since stress is concentrated in the air gap AG in the DTI region 910, cracks may occur along the upper side of the air gap AG. When a subsequent process such as a contact process is performed, for example, in a state where a crack occurring in the DTI region, tungsten (W) may remain inside the space created by the crack, causing a defect in the device.

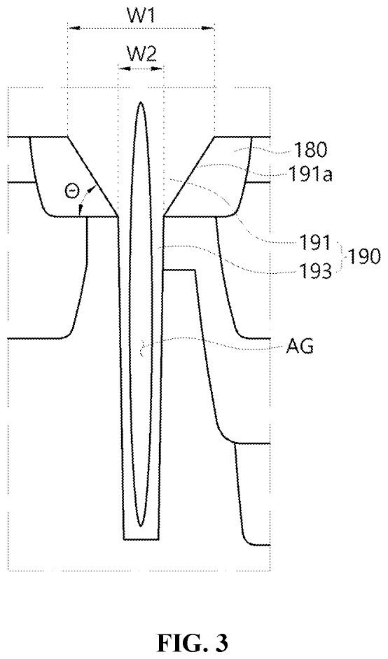

FIG. 3 is an enlarged view of a DTI region according to FIG. 2.

Referring to FIGS. 2 and 3, in order to solve the above problems, the DTI region 190 according to an embodiment of the present disclosure may include the upper region 191 and the lower region 193 extending downward from the lower end of the upper region 191 within the substrate 101. In this case, the upper region 191 may include an inclined surface 191a that becomes steeper as the outer surface thereof extends downward. The cross-section of the inclined surface 191a may have a substantially straight or curved shape, or may be formed to partially include both straight and curved shapes. Due to the inclined surface 191a, the upper region 191 may have a lateral width with the upper end thereof on the surface side of the substrate 101 is wider than the lower end thereof (W1>W2). In addition, the inclined surface 191a may be formed with an inclination angle (hereinafter referred to as “first inclination angle”) θ within the range of about 30° or more and 80° or less, but the scope of the present disclosure is not limited thereto.

As described above, in the present disclosure, the lateral width becomes narrower as the upper region 191 extends downward, so that when gap filling an insulating film, the upper end of an air gap AG created due to overhang on the boundary side of a first trench T1 for the substrate 101 and the upper region 191 may be formed at a relatively low height/depth. As such, when the upper end of the air gap AG is formed at low height/depth, even if a crack occurs in an insulating film 195 at the upper end of the air gap AG, for example, the possibility of the crack extending to the upper part of the insulating film 195 may be reduced. Thus, the possibility of causing defects in the device due to tungsten (W) remaining inside the space created by the crack may be significantly reduced when performing subsequent processes such as a contact process.

Furthermore, in the present disclosure, when forming the DTI region 190, a separate insulating film etch-back-secondary gap fill process is not performed, and thus process efficiency may be improved. That is, DTI region 190 is completed with only one gap fill process, and therefore, the insulating film 195 deposited on the surface of the substrate 101 to form the DTI region 190 remains as is.

Referring to FIG. 2, a compensation film 197 may be formed on the insulating film 195. The compensation film 197 is also composed of an insulating film and may form a PMD layer together with the insulating film 195. The compensation film 197 is a film for flattening the upper surface of the PMD layer, details of which will be explained in a method of manufacturing a semiconductor device to be described later.

A capping layer 199 including an insulating film may be formed on the compensation film 197. It should be noted that the capping layer 199 is a layer for controlling the overall thickness of the PMD layer, and is not an essential component of the present disclosure. The above-described insulating film 195, the compensation film 197, and the capping layer 199 may include, for example, a borophosphosilicate glass (BPSG) film and a tetraethyl orthosilicate (TEOS) film, and may be made of the same material or different materials, and there is no particular limitation thereon.

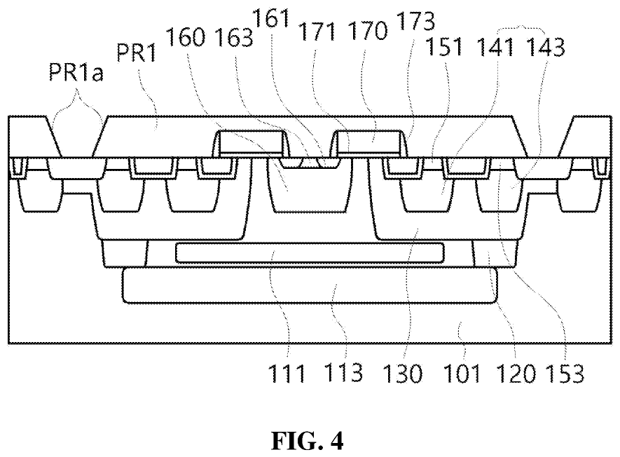

FIGS. 4 to 12 are cross-sectional views showing a method of manufacturing a semiconductor device including a DTI region according to an embodiment of the present disclosure.

Hereinafter, a method of manufacturing a semiconductor device including a DTI region according to an embodiment of the present disclosure will be described in detail with reference to the attached drawings. Below, for convenience of explanation, only the process of forming a DTI region 190 after well regions within a substrate 101 and a gate region including a gate electrode 170 are formed on the substrate 101 will be described in detail.

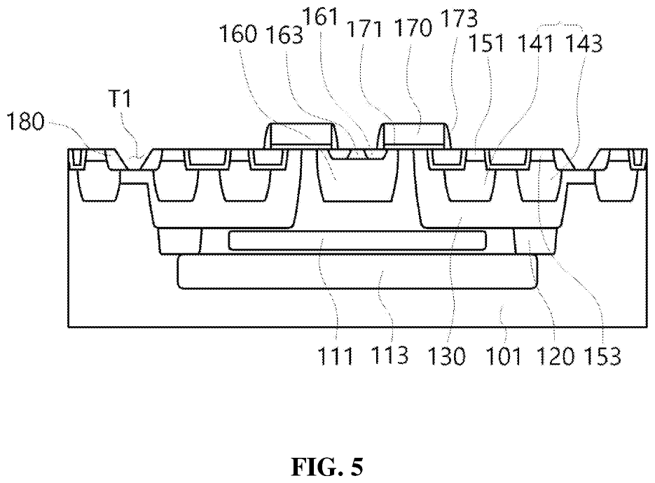

First, a first trench T1 in which an upper region 191 is to be formed is formed at a predetermined location within the substrate 101 (see FIG. 5). The first trench T1 may be formed on a side that overlaps an STI region 180 or may be formed on a side physically separated from the STI region 180 within the substrate 101, and there is no particular limitation thereon. In this case, the outer surface of the first trench T1 may be formed to be inclined as the outer surface of the first trench T1 extends downward. For example, the inner surface of the first trench T1 may have a substantially straight or curved shape, or may be formed to partially include both straight and curved shapes. In addition, the inner surface of the first trench T1 may have a lateral width with the upper end thereof is wider than the lower end thereof. As an example, a first inclination angle of the inner surface of the first trench T1 may be in the range of about 30° or more and 80° or less, but the scope of the present disclosure is not limited thereto.

In order to form the first trench T1 with the inclined inner surface in this way, referring to FIG. 4, a mask pattern PR1 is created on the substrate 101. The mask pattern PR1 is created such that the side where the first trench T1 is to be formed is open, and it is preferable that outer surfaces PR1a facing each other are inclined in a direction where the separation distance between the outer surfaces PR1a becomes narrower as the outer surfaces PR1a extend downward. Referring to FIG. 5, after creating the mask pattern PR1, the first trench T1 is completed by performing an etching process on the substrate 101, and the mask pattern PR1 is removed.

The described inclined first trench T1 may be formed by an etching process using the slope of the outer surface PR1a of the mask pattern PR1 as shown in FIG. 4, but may be formed by adjusting an etch recipe or any other process. That is, it should be noted that the first trench T1 according to an embodiment of the present disclosure may be manufactured using any process that allows the DTI region 190 to have an inclined surface 191a as shown in FIG. 3.

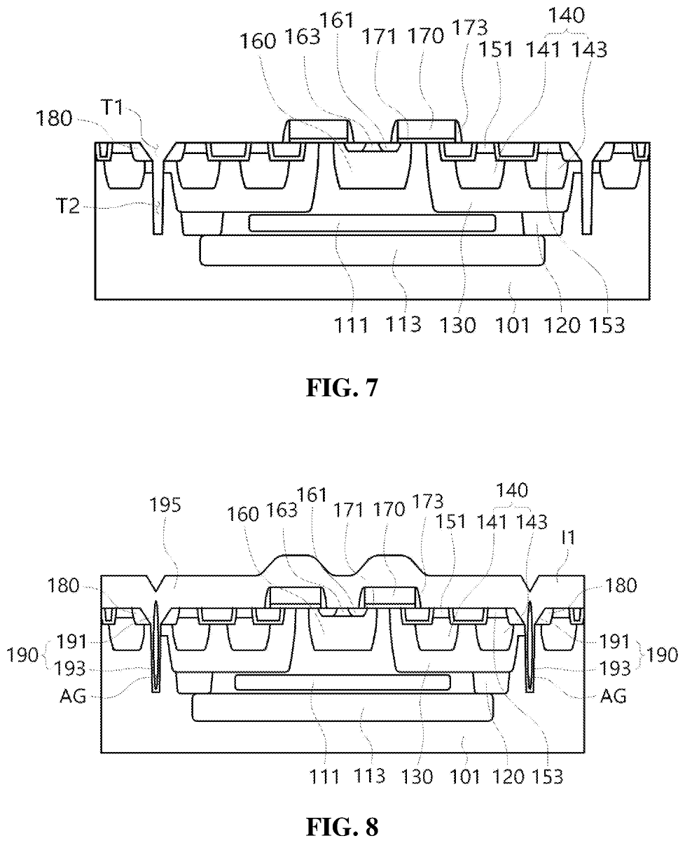

Thereafter, the substrate 101 under the first trench T1 is etched to form a second trench T2 (see FIG. 7). The second trench T2 is an area where a lower region 193 will be provided, and may be connected to the lower end of the first trench T1. At this time, the outer surface of the second trench T2 may be formed to extend substantially vertically or may be formed to be inclined, and there is no particular limitation thereon.

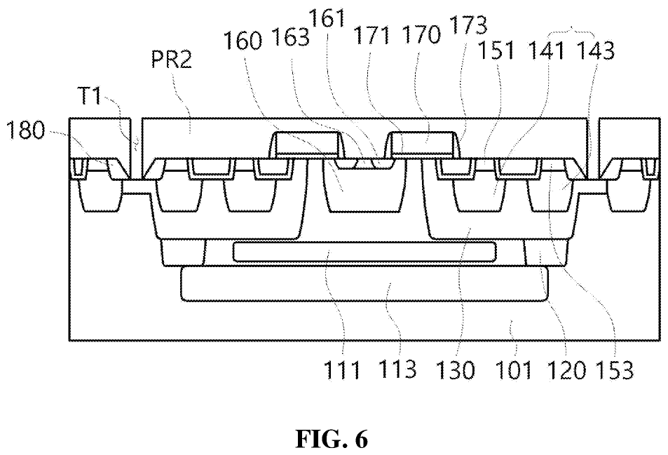

In order to form the second trench T2, referring to FIG. 6, a mask pattern PR2 is created on the substrate 101. The mask pattern PR2 is created such that the side where the second trench T2 is to be formed is open. Thereafter, referring to FIG. 7, the second trench T2 is completed by performing an etching process on the substrate 101 under the first trench T1, and the mask pattern PR2 is removed.

Thereafter, referring to FIG. 8, a first insulating film I1 is deposited on the substrate 101, and the first insulating film I1 is gap-filled in the first trench T1 and the second trench T2. Through this process, the DTI region 190 is completed, and an air gap AG may be formed within the DTI region 190. In addition, an insulating film 195 may be formed on the substrate 101. In this case, the upper end of the insulating film 195 may remain in a non-flattened state.

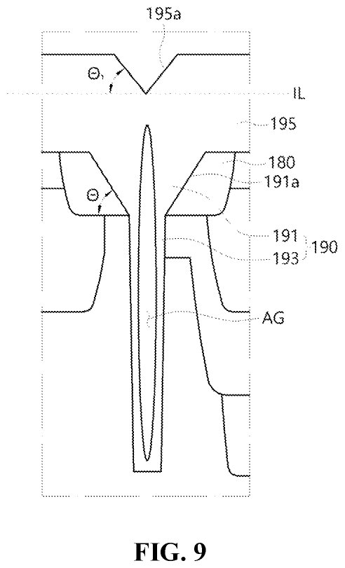

Referring to FIG. 9, at this time, the above-described upper region 191 and the lower region 193 are formed in the DTI region 190, and the inclined surface 191a may be formed in the upper region 191. As previously described, the first inclination angle θ of the inclined surface 191a may be in the range of about 30° or more and 80° or less, but the scope of the present disclosure is not limited thereto. The insulating film 195 immediately above the air gap AG may also include an inclined surface 195a on the upper surface thereof. In this case, the inclined surface 195a of the insulating film 195 may have a second inclination angle θ1 within a predetermined angle range with an imaginary line IL parallel to the substrate 101. The second inclination angle θ1 of the inclined surface 195a of the insulating film 195 may have a different size from the first inclination angle θ of the inclined surface 191a of the upper region 191, but the scope of the present disclosure is not limited thereto.

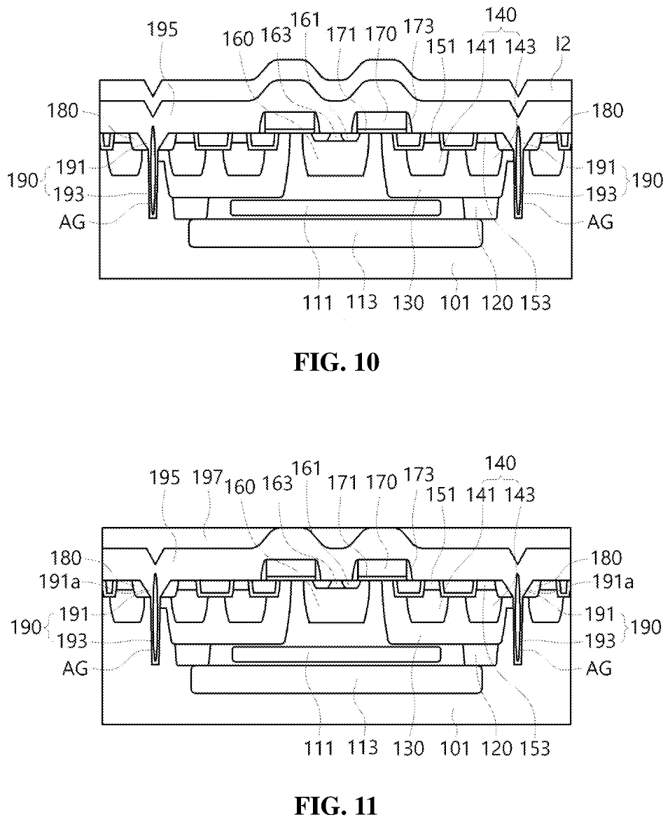

Thereafter, referring to FIG. 10, a second insulating film 12 is deposited on the insulating film 195 to form a compensation film 197. Thereafter, referring to FIG. 11, by performing a CMP process, the compensation film 197 with a substantially flat top surface may be completed.

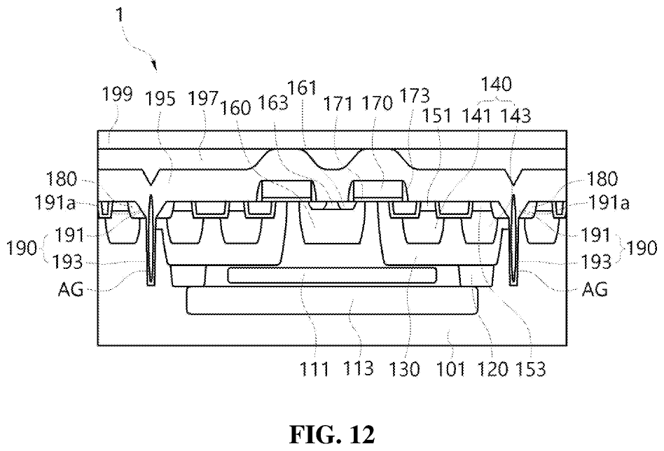

Finally, referring to FIG. 12, the total thickness of a PMD layer may be controlled by additionally forming a capping layer 199 on the compensation film 197, but it should be noted that this process is not an essential step of the present disclosure.

The above detailed description is illustrative of the present disclosure. In addition, the above description shows and describes preferred embodiments of the present disclosure, and the present disclosure can be used in various other combinations, modifications, and environments. That is, changes or modifications are possible within the scope of the concept of the disclosure disclosed herein, the scope equivalent to the written disclosure, and/or within the scope of skill or knowledge in the art. The above-described embodiment describes the best state for implementing the technical idea of the present disclosure, and various changes required in the specific application field and use of the present disclosure are possible. Accordingly, the detailed description of the present disclosure is not intended to limit the present disclosure to the disclosed embodiments.

What is claimed is:

1. A semiconductor device including a DTI region, the semiconductor device comprising:
a substrate; and
a DTI region disposed within the substrate,
wherein the DTI region comprises:
an upper region extending downward from a surface of the substrate to a first predetermined depth; and
a lower region extending downward from a bottom of the upper region to a second predetermined depth within the substrate,
wherein the upper region comprises an inclined surface that becomes steeper as an outer surface of the upper region extends downward.

2. The semiconductor device of claim 1, wherein an upper part of the upper region has a lateral width wider than a lateral width of a lower part of the upper region.

3. The semiconductor device of claim 1, wherein the inclined surface has an inclination angle within a range of 30° to 80°.

4. The semiconductor device of claim 1, wherein the DTI region is formed by a one-time insulating film gap fill process.

5. The semiconductor device of claim 1, further comprising:
an air gap defined in the DTI region.

6. The semiconductor device of claim 5, further comprising:
an insulating film disposed on the surface of the substrate,
wherein the inclined surface of the upper region has a first inclination angle,
wherein the insulating film comprises a second inclined surface that sinks downward at a second inclination angle above the air gap, and
wherein the second inclination angle has a different value from the first inclination angle.

7. The semiconductor device of claim 6, wherein the insulating film is formed substantially simultaneously with the DTI region.

8. The semiconductor device of claim 6, further comprising:
a compensation film disposed on the insulating film,
wherein the compensation film has a substantially flat upper surface.

9. The semiconductor device of claim 8, further comprising:
a capping layer configured to control an overall thickness of a PMD layer, the capping layer being disposed on the compensation film.

10. A semiconductor device including a DTI region, the semiconductor device comprising:
a substrate;
a gate electrode disposed on the substrate;
a drain region disposed on a substrate surface side within the substrate;
a source region spaced apart from the drain region and disposed on the substrate surface side within the substrate;
a body region surrounding the source region; and
a DTI region disposed within the substrate,
wherein the DTI region comprises:
an upper region whose outer surface extends downward from a surface of the substrate to a first predetermined depth; and
a lower region extending downward from a bottom of the upper region to a second predetermined depth within the substrate.

11. The semiconductor device of claim 10, further comprising:
an STI region disposed on a side that overlaps the DTI region within the substrate.

12. The semiconductor device of claim 10, wherein the upper region has a wider lateral width than a later width of the lower region.

13. The semiconductor device of claim 10, wherein an upper part of the upper region has a lateral width wider than a lateral width of a lower part of the upper region.

14. The semiconductor device of claim 10, further comprising:
a first buried layer disposed in the substrate;
a second buried layer disposed within the substrate and below the first buried layer;
a high voltage well region connected to a side of the second buried layer; and
a deep well region surrounding the drain region within the substrate and disposed on the high voltage well region.

15. The semiconductor device of claim 10, wherein the upper region is formed using a mask pattern, wherein the mask pattern is formed such that a side of the substrate where the upper region is to be formed is open, and outer surfaces of the mask pattern facing each other are inclined downward and a separation distance between the outer surfaces becomes narrower as the outer surfaces extend downward.

16. A method of manufacturing a semiconductor device including a DTI region, the method comprising:
forming, at a predetermined location in a substrate, a first trench whose inner walls extend and incline downward;
forming a second trench by etching the substrate under the first trench; and
completing an insulating film and a DTI region by depositing a first insulating film on the substrate and gap-filling the first insulating film in the first trench and the second trench.

17. The method of claim 16, further comprising:
completing a compensation film on the insulating film on the substrate.

18. The method of claim 17, wherein the completing of the compensation film comprises:
depositing a second insulating film on the insulating film; and
flattening an upper surface of the second insulating film.

19. The method of claim 17, further comprising:
depositing a capping layer on the compensation film.

20. The method of claim 16, wherein the first trench is formed so that the inner walls thereof facing each other are adjacent to each other as the inner walls extend downward.
